(19) United States
(12) Patent Application Publication
(10) Pub. No.: US 2025/0318324 A1
(43) Pub. Date: Oct. 9, 2025

(54) SEMICONDUCTOR DEVICE

(71) Applicant: EPISTAR CORPORATION, Hsinchu (TW)

(72) Inventors: Yen-Kai YANG, Hsinchu (TW); Yi-Chieh LIN, Hsinchu (TW); Kuo-Feng HUANG, Hsinchu (TW); Wen-Di HUANG, Hsinchu (TW); Cheng-Yu KAO, Hsinchu (TW)

(21) Appl. No.: 19/098,682

(22) Filed: Apr. 2, 2025

(30) Foreign Application Priority Data
Apr. 3, 2024 (TW) 113112819

(51) Int. Cl. H10H 20/824; H01S 5/02315; H01S 5/30; H10F 77/00; H10F 77/124; H10H 20/857

(52) U.S. Cl. CPC H10H 20/8242; H01S 5/02315; H01S 5/3013; H01S 5/3086; H10F 77/1243; H10F 77/1248; H10F 77/935; H10H 20/857

(57) ABSTRACT

A semiconductor device is provided, which includes an epitaxial structure. The epitaxial structure includes a first semiconductor structure, a second semiconductor structure, and an active region. The first semiconductor structure has a first conductivity type and includes a first intermediate layer and a first cladding layer. The second semiconductor structure has a second conductivity type. The active region is located between the first semiconductor structure and the second semiconductor structure. The first intermediate layer is located between the active region and the first cladding layer. The first intermediate layer includes P or As. The first intermediate layer and the first cladding layer include a first dopant. A maximum concentration of the first dopant in the first intermediate layer is greater than a maximum concentration of the first dopant in the first cladding layer.

### CROSS REFERENCE TO RELATED APPLICATIONS

This application claims the right of priority based on TW application Ser. No. 11/311,2819, filed on Apr. 3, 2024, which is incorporated by reference herein in its entirety.

### FIELD OF DISCLOSURE

The present disclosure relates to a semiconductor device, and in particular to a semiconductor optoelectronic device.

### BACKGROUND OF THE DISCLOSURE

Group III-V semiconductor materials including Group III and Group V elements may be used to produce various semiconductor devices, such as semiconductor optoelectronic devices like light-emitting diodes (LEDs), laser diodes (LDs), photodetectors or solar cells, or may be used in power devices, such as switching devices or rectifiers. These semiconductor optoelectronic devices may be applied to products in various fields, such as illumination, medical, display, communication, sensing or power supply system. Light-emitting diodes and laser diodes are light-emitting devices, and their basic structures may include a p-type semiconductor, an n-type semiconductor and an active region located between the p-type semiconductor and the n-type semiconductor. By introducing current, carriers may recombine in the active region and emit light, and wavelength of the light depends on the semiconductor material in the active region.

### SUMMARY OF THE DISCLOSURE

The present disclosure provides a semiconductor device. The semiconductor device includes an epitaxial structure. The epitaxial structure includes a first semiconductor structure, a second semiconductor structure, and an active region. The first semiconductor structure has a first conductivity type and includes a first intermediate layer and a first cladding layer. The second semiconductor structure has a second conductivity type. The active region is located between the first semiconductor structure and the second semiconductor structure. The first intermediate layer is located between the active region and the first cladding layer. The first intermediate layer includes P or As. The first intermediate layer and the first cladding layer include a first dopant. A maximum concentration of the first dopant in the first intermediate layer is greater than a maximum concentration of the first dopant in the first cladding layer.

The present disclosure further provides a semiconductor component. The semiconductor component includes a carrier, a semiconductor device located on the carrier, and a first conductive bump and a second conductive bump located between the semiconductor device and the carrier. The semiconductor device includes an epitaxial structure. The epitaxial structure includes a first semiconductor structure, a second semiconductor structure, and an active region. The first semiconductor structure has a first conductivity type and includes a first intermediate layer and a first cladding layer. The second semiconductor structure has a second conductivity type. The active region is located between the first semiconductor structure and the second semiconductor structure. The first intermediate layer is located between the active region and the first cladding layer. The first intermediate layer includes P or As. The first intermediate layer and the first cladding layer include a first dopant. A maximum concentration of the first dopant in the first intermediate layer is greater than a maximum concentration of the first dopant in the first cladding layer.

### BRIEF DESCRIPTION OF THE DRAWINGS

FIG. 1 shows a schematic sectional view of an epitaxial structure in accordance with an embodiment of the present disclosure.

FIG. 2 shows a schematic sectional view of an epitaxial structure in accordance with an embodiment of the present disclosure.

FIG. 3 shows a schematic sectional view of an epitaxial structure in accordance with an embodiment of the present disclosure.

FIG. 4 shows a schematic sectional view of an epitaxial structure in accordance with an embodiment of the present disclosure.

FIG. 5 shows a schematic sectional view of an epitaxial structure in accordance with an embodiment of the present disclosure.

FIG. 6 shows a schematic sectional view of an epitaxial structure in accordance with an embodiment of the present disclosure.

FIG. 7 shows a schematic sectional view of an epitaxial structure in accordance with an embodiment of the present disclosure.

FIG. 8 shows a schematic sectional view of an epitaxial structure in accordance with an embodiment of the present disclosure.

FIG. 9 shows a schematic sectional view of an epitaxial structure in accordance with an embodiment of the present disclosure.

FIG. 10 shows a diagram of dopant concentration in a partial region of the epitaxial structure of FIG. 3.

FIG. 11A shows a schematic top view of a semiconductor device in accordance with an embodiment of the present disclosure.

FIG. 11B shows a schematic sectional view of a semiconductor device in accordance with an embodiment of the present disclosure.

FIG. 12A shows a schematic sectional view of a semiconductor component in accordance with an embodiment of the present disclosure.

FIG. 12B shows a schematic top view of a semiconductor component in accordance with an embodiment of the present disclosure.

### DETAILED DESCRIPTION OF THE DISCLOSURE

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

The semiconductor device of the present disclosure is, for example, a semiconductor optoelectronic device or a non-illumination device. The semiconductor optoelectronic device includes a light-emitting device (such as a light-emitting diode or a laser diode), or a light absorbing device (such as a photo-detector). The qualitative or quantitative analysis of the composition and/or dopant contained in each layer of the semiconductor device of the present disclosure may be conducted by any suitable method, for example, by secondary ion mass spectrometer (SIMS) or electrochemical capacitance-voltage (ECV). A thickness of each layer may be obtained by any suitable method, for example, by transmission electron microscopy (TEM) or scanning electron microscope (SEM).

Those with ordinary knowledge in the art should understand that other member(s) may be added on the basis of each embodiment described below. For example, if not otherwise specified, a description similar to “a first layer/structure is on or under a second layer/structure” may include an embodiment in which the first layer/structure is in direct contact with (or physically/directly contacts) the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

In the present disclosure, if not otherwise specified, the general formula InGaP represents Inₓ₀Ga₁₋ₓ₀P, wherein 0<x0<1; the general formula AlInP represents Alₓ₁In₁₋ₓ₁P, wherein 0<x1<1; the general formula InGaN represents Inₓ₂Ga₁₋ₓ₂N, wherein 0<x2<1; the general formula AlGaN represents Alₓ₃Ga₁₋ₓ₃N, wherein 0<x3<1; the general formula AlGaInP represents Alₓ₄Gaₓ₅In₁₋ₓ₄-x5P, wherein 0<x4<1, and 0<x5<1; the general formula InGaAsP represents Inₓ₆Ga₁₋ₓ₆ASₓ₇P₁₋ₓ₇, wherein 0<x6<1, and 0<x7<1; the general formula AlGaInAs represents Alₓ₈Gaₓ₉In₁₋ₓ₈₋ₓ₉As, wherein 0<x8<1, and 0<x9<1; the general formula InGaAs represents Inₓ₁₀Ga₁₋ₓ₁₀As, wherein 0<x10<1; the general formula AlGaAs represents Alₓ₁₁Ga₁₋ₓ₁₁As, wherein 0<x11<1; and the general formula AlGaAsP represents Alₓ₁₂Ga₁₋ₓ₁₂Asₓ₁₃P₁₋ₓ₁₃, wherein 0<x12<1, and 0<x13<1.

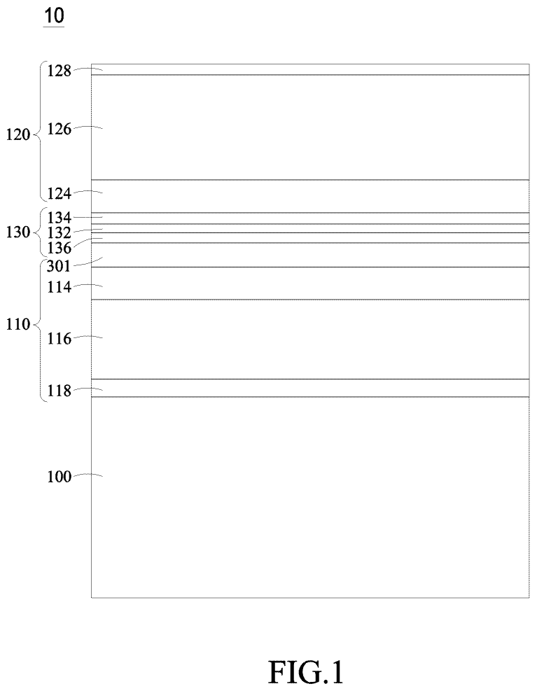

Specifically, the semiconductor device of the present disclosure may include an epitaxial structure as shown in FIG. 1 to FIG. 9. Each epitaxial structure will be described in detail below.

FIG. 1 shows a schematic sectional view of an epitaxial structure 10 in accordance with an embodiment of the present disclosure. As shown in FIG. 1, the epitaxial structure 10 includes a first semiconductor structure 110, a second semiconductor structure 120, and an active region 130. The active region 130 is located between the first semiconductor structure 110 and the second semiconductor structure 120. The first semiconductor structure 110, the second semiconductor structure 120 and the active region 130 can be obtained by epitaxial growth. Methods for epitaxy growth include but are not limited to metal-organic chemical vapor deposition (MOCVD), hydride vapor phase epitaxy (HVPE), molecular beam epitaxy (MBE) or liquid-phase epitaxy (LPE). The first semiconductor structure 110 and the second semiconductor structure 120 may include a single layer or multiple layers, and each layer may include a group III-V semiconductor material. The group III-V semiconductor material may include aluminum (Al), gallium (Ga), arsenic (As), phosphorus (P), indium (In) or nitrogen (N). In an embodiment, each layer in the first semiconductor structure 110, the second semiconductor structure 120, and the active region 130 includes indium or arsenic.

The first semiconductor structure 110 has a first conductivity type. The second semiconductor structure 120 has a second conductivity type different from the first conductivity type. The first semiconductor structure 110 and the second semiconductor structure 120 may provide electrons and holes (or holes and electrons) respectively. For example, the first conductivity type is n-type and the second conductivity type is p-type, or the first conductivity type is p-type and the second conductivity type is n-type. The conductivity type of the first semiconductor structure 110 and the second semiconductor structure 120 can be adjusted by adding different dopants. For example, the first semiconductor structure 110 includes a first dopant, and the second semiconductor structure 120 includes a second dopant which is different from the first dopant. Each of the first dopant and the second dopant may be a Group II, Group IV or Group VI element in the periodic table, such as magnesium (Mg), zinc (Zn), carbon (C), silicon (Si) or tellurium (Te). In an embodiment, the first dopant is silicon (Si) and the second dopant is magnesium (Mg), or the first dopant is magnesium (Mg) and the second dopant is silicon (Si).

The electrons and holes can be combined in the active region 130 to emit a light with a peak wavelength. The light can be visible light or invisible light, and can be incoherent light or coherent light. Specifically, the peak wavelength can be determined by the material composition of the active region 130. For example, when the material of the active region 130 includes AlGaN, it may emit ultraviolet light with a peak wavelength of 250 nm to 400 nm; when the material of the active region 130 includes InGaN, it may emit deep blue light or blue light with a peak wavelength of 400 nm to 490 nm, green light with a peak wavelength of 490 nm to 550 nm, or yellow or red light with a peak wavelength of 560 nm to 650 nm; when the material of the active region 130 includes InGaP or AlGaInP, it may emit yellow light, orange light or red light with a peak wavelength of 530 nm to 700 nm; when the material of the active region 130 includes InGaAs, InGaAsP, AlGaAs or AlGaInAs, it may emit infrared light with a peak wavelength of 700 nm to 1700 nm.

As shown in FIG. 1, the first semiconductor structure 110 is multi-layered and may include a first cladding layer 114 and a first intermediate layer 301. The second semiconductor structure 120 may include a second cladding layer 124. In this embodiment, the first intermediate layer 301 is located between the active region 130 and the first cladding layer 114. As shown in FIG. 1, the first intermediate layer 301 may be adjacent to the active region 130 and the first cladding layer 114. In this embodiment, the first intermediate layer 301 has the same conductivity type as the first cladding layer 114. In this embodiment, the first intermediate layer 301 does not contain the second dopant. The first intermediate layer 301 and the first cladding layer 114 may include the first dopant and has the first conductivity type. The second cladding layer 124 may include a second dopant and has the second conductivity type.

The first intermediate layer 301 may include phosphorus or arsenic. According to an embodiment, the first intermediate layer 301 includes a ternary group III-V semiconductor material (such as InGaAs, AlGaAs, InGaP or AlInP) or a quaternary group III-V semiconductor material (such as AlGaInAs, AlGaInP, InGaAsP or AlGaAsP). The first cladding layer 114 may include phosphorus or arsenic. The second cladding layer 124 may include phosphorus or arsenic. According to an embodiment, each of the first cladding layer 114 and the second cladding layer 124 may include a ternary group III-V semiconductor materials (such as InGaAs, AlGaAs, InGaP, or AlInP) or a quaternary group III-V semiconductor materials (such as AlGaInAs, AlGaInP, InGaAsP, or AlGaAsP). The material of the first intermediate layer 301 and the first cladding layer 114 may be the same or different. The material of the first intermediate layer 301 and the second cladding layer 124 may be the same or different. In an embodiment, the first intermediate layer 301 and the first cladding layer 114 may include one or more identical elements, such as Al, In, or P. In an embodiment, the first intermediate layer 301 and the second cladding layer 124 may include one or more identical elements, such as Al, In, or P. In an embodiment, the first intermediate layer 301 and the first cladding layer 114 both include ternary group III-V semiconductor materials (such as AlInP), and the second cladding layer 124 includes a quaternary group III-V semiconductor material (such as AlGaInP). In an embodiment, the first intermediate layer 301, the first cladding layer 114 and the second cladding layer 124 all include ternary group III-V semiconductor materials (such as AlInP). In an embodiment, the first cladding layer 114 and the second cladding layer 124 both include ternary group III-V semiconductor materials (such as AlInP), and the first intermediate layer 301 includes a quaternary group III-V semiconductor material (such as AlGaInP).

The first dopant in the first cladding layer 114 may have a maximum concentration and a minimum concentration. The first dopant in the first intermediate layer 301 may have a maximum concentration and a minimum concentration. The maximum concentration of the first dopant in the first intermediate layer 301 can be in a range of greater than or equal to 2×10¹⁸ cm⁻³ and less than or equal to 8×10¹⁸ cm⁻³, such as 3×10¹⁸ cm⁻³ to 7×10¹⁸ cm⁻³. The maximum concentration of the first dopant in the first cladding layer 114 can be in the range of greater than or equal to 1×10¹⁸ cm⁻³ and less than or equal to 4×10¹⁸ cm⁻³, such as 1.5×10¹⁸ cm⁻³ to 3.8×10¹⁸ cm⁻³. The maximum concentration of the first dopant in the first intermediate layer 301 may be greater than, equal to, or lower than the maximum concentration of the first dopant in the first cladding layer 114. A ratio of the maximum concentration of the first dopant in the first intermediate layer 301 to the maximum concentration of the first dopant in the first cladding layer 114 may be in a range of 0.5 to 8, such as greater than 1 and less than or equal to 5. According to an embodiment, the first intermediate layer 301 is formed, for example, by increasing a doping concentration compared to the doping concentration in a cladding layer that is closest to the first intermediate layer 301 (the first cladding layer 114 in this embodiment) during the epitaxial growth process. The minimum concentration of the first dopant in the first intermediate layer 301 may be greater than the minimum concentration of the first dopant in the first cladding layer 114. The minimum concentration of the first dopant in the first intermediate layer 301 is, for example, within a range of 70% to 99% (such as 75% to 85%) of the maximum concentration of the first dopant in the first intermediate layer 301. The minimum concentration of the first dopant in the first cladding layer 114 is, for example, within the range of 70% to 99% (such as 75% to 85%) of the maximum concentration of the first dopant in the first cladding layer 114. A thickness of the first intermediate layer 301 may range from greater than or equal to 200 Åto less than or equal to 1000 Å. According to an embodiment, by arranging the first intermediate layer 301 in the first semiconductor structure 110, a capacitance can be further increased, and the anti-electrostatic discharge (anti-ESD) capability of the semiconductor device including the epitaxial structure 10 can be improved.

As shown in FIG. 1, the first semiconductor structure 110 may further optionally include a first window layer 116 and a first contact layer 118. The first window layer 116 is located between the first cladding layer 114 and the first contact layer 118. The second semiconductor structure 120 may further optionally include a second window layer 126 and a second contact layer 128. The second window layer 126 is located between the second cladding layer 124 and the second contact layer 128. The first window layer 116 and the first contact layer 118 may include the first dopant and have the first conductivity type. The second window layer 126 and the second contact layer 128 may include the second dopant and have the second conductivity type. The first window layer 116 and the second window layer 126 can be transparent to the light emitted by the active region 130, which helps to increase the light extraction efficiency and/or uniformity of current distribution of the epitaxial structure 10. According to an embodiment, the first window layer 116 and the second window layer 126 may include a binary group III-V semiconductor materials (such as GaAs or GaP), a ternary group III-V semiconductor material (such as InGaAs, AlGaAs, InGaP, or AlInP), or a quaternary group III-V semiconductor material (such as AlGaInAs, AlGaInP, InGaAsP, or AlGaAsP). In an embodiment, the first window layer 116 includes a ternary group III-V semiconductor material (such as AlInP) or a quaternary group III-V semiconductor material (such as AlGaInP), and the second window layer 126 includes a binary group III-V semiconductor material (such as GaP). In an embodiment, the first window layer 116 includes AlnGamIn₁₋ₙ₋ₘP, where 0<n<1 and 0<m<1, for example, 0.1≤n≤0.3 and 0.25m≤0.4. In an embodiment, by setting n to be less than or equal to 0.2, the current spreading effect can be further improved.

The first window layer 116 and the second window layer 126 may have different thicknesses. For example, the thickness of the first window layer 116 is in a range of 2 um to 5 um, and the thickness of the second window layer 126 is in a range of 6 um to 15 um. According to an embodiment, the thickness of the second window layer 126 may be 1.2 to 7.5 times (such as 1.5 to 5 times) the thickness of the first window layer 116. According to an embodiment, the first window layer 116 and the second window layer 126 having these thickness range(s) and/or ratio(s) can help to improve current diffusion and enhance anti-ESD capability. The first dopant may have a maximum concentration and a minimum concentration in the first window layer 116. The maximum concentration of the first dopant in the first window layer 116 is, for example, in a range of greater than or equal to 1×10¹⁸ cm⁻³ and less than or equal to 5×10¹⁸ cm⁻³. The maximum concentration of the second dopant in the second window layer 126 is, for example, in a range of greater than or equal to 5×10¹⁷ cm⁻³ and less than or equal to 3×10¹⁸ cm⁻³. According to an embodiment, the maximum concentration of the first dopant in the first window layer 116 or the maximum concentration of the second dopant in the second window layer 126 reaches 2×10¹⁸ cm⁻³ or more (such as 2.5×10¹⁸ cm⁻³ or 3×10¹⁸ cm⁻³) helps to further improve the anti-ESD capability.

The first contact layer 118 and the second contact layer 128 can form good contact (such as ohmic contact) with a metal material. According to an embodiment, the first contact layer 118 and the second contact layer 128 may include a binary group III-V semiconductor material (such as GaAs or GaP). The first dopant may have a maximum concentration and a minimum concentration in the first contact layer 118. The first dopant may have a maximum concentration and a minimum concentration in the first window layer 116. The first dopant may have maximum concentrations and minimum concentrations in the first contact layer 118 and the first window layer 116. The maximum concentration of the first dopant in the first contact layer 118 may be greater than the maximum concentration of the first dopant in the first window layer 116. The second dopant may have a maximum concentration and a minimum concentration in the second contact layer 128. The maximum concentration of the second dopant in the second contact layer 128 can be greater than the maximum concentration of the second dopant in the second window layer 126, so as to facilitate the formation of ohmic contact with the metal material. The maximum concentration of the first dopant in the first contact layer 118 is, for example, in a range of greater than or equal to 5×10¹⁷ cm⁻³ and less than or equal to 5×10¹⁸ cm⁻³. The maximum concentration of the second dopant in the second contact layer 128 is, for example, in a range of greater than or equal to 3×10¹⁸ cm⁻³ and less than or equal to 1×10²⁰ cm⁻³. According to an embodiment, the relationship between the maximum concentrations of the first dopant in each layer of the first semiconductor structure 110 can be: the first contact layer 118≥first intermediate layer 301>the first window layer 116>the first cladding layer 114; or, the first contact layer 118>the first window layer 116≥the first intermediate layer 301>the first cladding layer 114. According to an embodiment, the relationship between the minimum concentrations of the first dopant in each layer of the first semiconductor structure 110 can be: the first contact layer 118≥the first intermediate layer 301>the first window layer 116≥the first cladding layer 114; or, the first contact layer 118>the first window layer 116≥the first intermediate layer 301>the first cladding layer 114.

In an embodiment, the second semiconductor structure 120 may further optionally include a transition structure (not shown) between the second window layer 126 and the second cladding layer 124. According to an embodiment, the material of the transition structure may include Al_{y1}Ga_{y2}In_{1-y1-y2}P, in which 0≤y1<1 and 0<y2<1. In an embodiment, an Al (aluminum) content in the transition structure can decrease from one side to the other side, for example, y1 can decrease from 0.95 to 0. Specifically, the aluminum content in the transition structure can be decreased in a direction from the second cladding layer 124 to the second window layer 126. The reduction in aluminum content can be linear or non-linear. As an embodiment, the aluminum content can be decreased in a gradual or stepwise manner. When there is a lattice mismatch between the material of the second window layer 126 and the material of the second cladding layer 124, the transition structure can be used as a buffer between these two layers to improve the stability of the epitaxial structure 10. The transition structure may contain a second dopant. The second dopant may have a maximum concentration and a minimum concentration in the transition structure. The maximum concentration of the second dopant in the transition structure is, for example, in a range of greater than or equal to 5×10¹⁷ cm⁻³ and less than or equal to 2×10¹⁸ cm⁻³.

The active region 130 may optionally include a light-emitting region 132 having N pairs of semiconductor layers, where N is a positive integer greater than or equal to 1 and less than or equal to 30 (for example, in a range of 5 to 18). Each pair of semiconductor layers includes a well layer (not shown) and a barrier layer (not shown) adjacent to the well layer. The active region 130 may further optionally include a first confinement layer 134 and a second confinement layer 136. In this embodiment, as shown in FIG. 1, the first confinement layer 134 may be adjacent to the second cladding layer 124 in the second semiconductor structure 120, and the second confinement layer 136 can be adjacent to the first intermediate layer 301 in the first semiconductor structure 110. The first confinement layer 134 and the second confinement layer 136 may have an energy gap greater than or equal to an energy gap of the barrier layer, so as to improve the ability of the active region 130 to confine carriers and increase the probability of carrier recombination to emit light.

In an embodiment, the light-emitting region 132, the first confinement layer 134, and the second confinement layer 136 include a ternary group III-V semiconductor material (such as InGaAs, AlGaAs, InGaP, or AlInP) or a quaternary group III-V semiconductor material (such as AlGaInAs, AlGaInP, InGaAsP, or AlGaAsP). In an embodiment, the material of the first confinement layer 134 and/or the second confinement layer 136 includes Al_{z1}Ga_{z2}In_{1-z1-z2}P, in which 0≤z1≤1 and 0≤z2≤1, for example, 0.35≤z1≤0.5 and 0≤z2≤0.15. In an embodiment, z1 greater than 0.4 is beneficial to further improving the anti-ESD capability. A thickness of the barrier layer in each pair of semiconductor stacks may range from 20Å to 90 Å. A thickness of the well layer in each pair of semiconductor stacks may range from 30 Å to 60 Å. The thickness of the barrier layer may be greater than, less than, or equal to the thickness of the well layer. The thickness of the first confinement layer 134 may be greater than, less than, or equal to the thickness of the second confinement layer 136. In an embodiment, the thicknesses of the first confinement layer 134 and the second confinement layer 136 may be in a range from 100 Å to 1000 Å. In an embodiment, a ratio of the thickness of the second confinement layer 136 to the thickness of the first confinement layer 134 may be in a range of 0.1 to 10 (such as 1.5 to 3). In an embodiment, the ratio of the thickness of the second confinement layer 136 to the thickness of the first confinement layer 134 is between 1.5 and 3, which can help to avoid a situation that the second dopant diffuses into the active region 130 and affects the reliability of the semiconductor device. In an embodiment, the thickness of the first confinement layer 134 or the thickness of the second confinement layer 136 is less than 500 Å, which is beneficial to improving the anti-ESD capability. According to an embodiment, a total thickness of the active region 130 may be in a range of 1500 Å to 4000 Å to increase the capacitance of the epitaxial structure, which is beneficial to improving the anti-ESD capability.

As shown in FIG. 1, the epitaxial structure 10 may further optionally include a base 100. In this embodiment, the epitaxial structure 10 is located on the base 100. In an embodiment, the base 100 is a growth substrate, that is, epitaxial growth can be performed on the base 100. In another embodiment, the base 100 may be a bonding substrate rather than a growth substrate. The bonding substrate may be bonded to the epitaxial structure 10 through an adhesive layer (not shown). The base 100 may include a conductive or insulating material. The conductive may be gallium arsenide (GaAs), indium phosphide (InP), silicon carbide (SiC), and gallium phosphide (GaP), zinc oxide (ZnO), gallium nitride (GaN), aluminum nitride (AlN), germanium (Ge) or silicon (Si). The insulating materials may be sapphire, glass, diamond, aluminum nitride (AlN), quartz, acrylic, or epoxy resin.

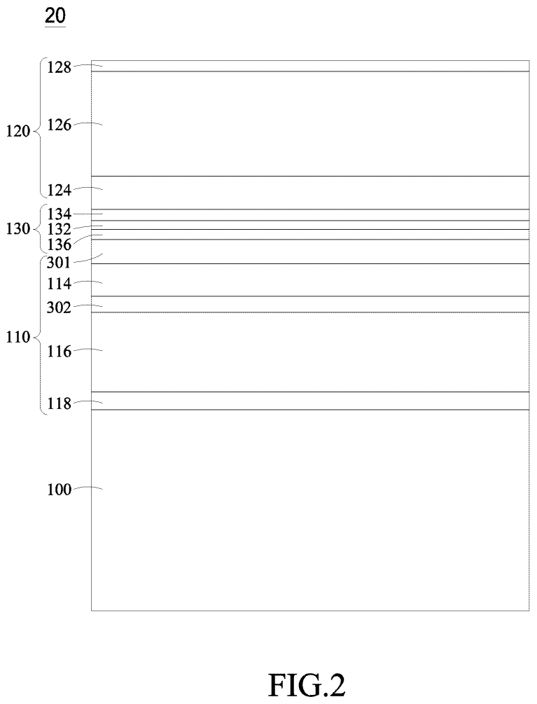

FIG. 2 shows a schematic sectional view of an epitaxial structure 20 in accordance with an embodiment of the present disclosure. The main difference between the epitaxial structure 20 and the epitaxial structure 10 is that the first semiconductor structure 110 in the epitaxial structure 20 further includes a second intermediate layer 302, and the first cladding layer 114 is located between the first intermediate layer 301 and the second intermediate layer 302. As shown in FIG. 2, the second intermediate layer 302 may be adjacent to the first cladding layer 114 and the first window layer 116. The second intermediate layer 302 may include phosphorus (P) or arsenic (As). According to an embodiment, the second intermediate layer 302 includes a ternary group III-V semiconductor material (such as InGaAs, AlGaAs, InGaP, or AlInP) or a quaternary group III-V semiconductor material (such as AlGaInAs, AlGaInP, InGaAsP, or AlGaAsP). In an embodiment, the second intermediate layer 302, the first intermediate layer 301, and the first cladding layer 114 may have one or more identical elements, such as Al, In, or P.

The second intermediate layer 302 may include the first dopant. In this embodiment, the first intermediate layer 301 and the second intermediate layer 302 have the same conductivity type. The first dopant in the second intermediate layer 302 may have a maximum concentration and a minimum concentration. According to an embodiment, the minimum concentration of the first dopant in the second intermediate layer 302 is lower than the minimum concentration of the first dopant in the first cladding layer 114. The minimum concentration of the first dopant in the second intermediate layer 302 is, for example, in a range of greater than or equal to 1×10¹⁶ cm⁻³ and less than or equal to 6×10¹⁷ cm⁻³. The second intermediate layer 302 is formed, for example, by decreasing doping concentration during epitaxial growth. In this embodiment, the second intermediate layer 302 may have a greater resistance than the first cladding layer 114, so that when current passes through, the current can spread laterally first, thereby improving current diffusion. A thickness of the second intermediate layer 302 may be in a range of 300 Å to 1000 Å. The minimum concentration of the first dopant in the second intermediate layer 302 can be equal to or less than ½ (for example, in a range of 3/10 to 1/800) of the maximum concentration of the first dopant in the first intermediate layer 301. The minimum concentration of the first dopant in the second intermediate layer 302 may be equal to or less than 3/42 (for example, in a range of 3/5 to 1/400) of the maximum concentration of the first dopant in the first cladding layer 114. According to some embodiments, the resistance of the second intermediate layer 302 can be increased through the above concentration design, which may help to improve current spreading.

According to an embodiment, relationships between the maximum concentrations of the first dopant in each layer of the first structure semiconductor 110 can be: the first contact layer 118≥the first intermediate layer 301≥the second intermediate layer 302>the first window layer 116≥the first cladding layer 114; or, the first contact layer 118>the first window layer 116≥the first intermediate layer 301>the first cladding layer 114>the second intermediate layer 302. According to an embodiment, relationships between the minimum concentrations of the first dopant in each layer of the first semiconductor structure 110 can be: the first contact layer 118≥first intermediate layer 301>the first window layer 116≥the first cladding layer 114>the second intermediate layer 302; or, the first contact layer 118>the first window layer 116≥the first intermediate layer 301>the first cladding layer 114>the second intermediate layer 302. According to an embodiment, by arranging the second intermediate layer 302 in the epitaxial structure, the current spreading ability can be increased, and it can also help to improve the anti-ESD capability of the semiconductor device including the epitaxial structure 20. The detailed descriptions of positions, relative relationships and materials of each layer or structure as well as structural variations of the epitaxial structure 20 may be referred to the forward embodiments and are not repeatedly described herein.

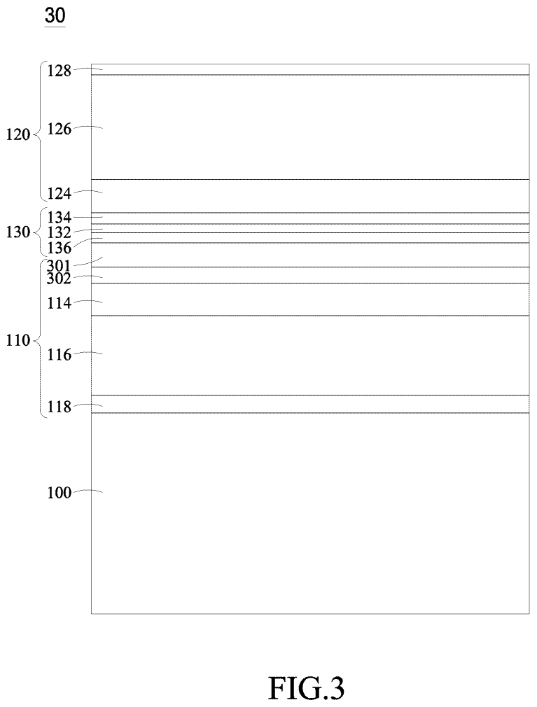

FIG. 3 shows a schematic sectional view of an epitaxial structure 30 in accordance with an embodiment of the present disclosure. The main difference between the epitaxial structure 30 and the epitaxial structure 20 is the position of the second intermediate layer 302. As shown in FIG. 3, in the epitaxial structure 30, the first intermediate layer 301 is located between the active region 130 and the first cladding layer 114, and the second intermediate layer 302 is located between the first intermediate layer 301 and the first cladding layer 114. As shown in FIG. 3, the second intermediate layer 302 may be adjacent to the first intermediate layer 301 and the first cladding layer 114. In another embodiment, the first intermediate layer 301 may be located between the active region 130 and the first cladding layer 114, and the second intermediate layer 302 may be located between the first intermediate layer 301 and the active region 130. The detailed descriptions of positions, relative relationships and materials of each layer or structure as well as structural variations of the epitaxial structure 30 may be referred to the forward embodiments and are not repeatedly described herein.

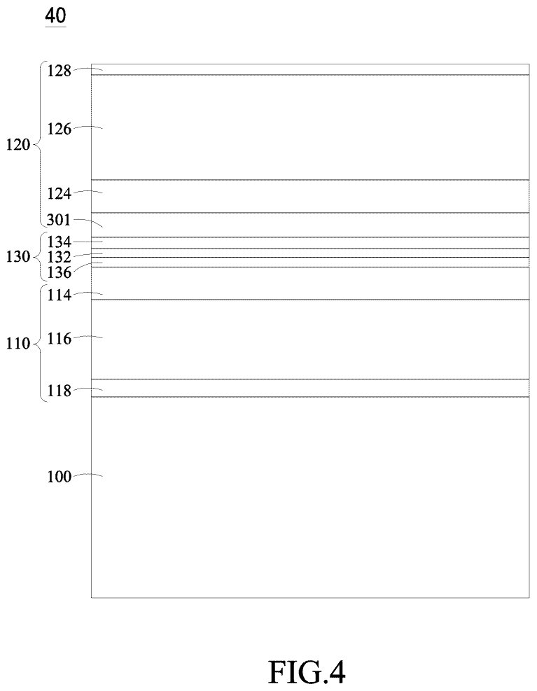

FIG. 4 shows a schematic sectional view of an epitaxial structure 40 in accordance with an embodiment of the present disclosure. The main difference between the epitaxial structure 40 and the epitaxial structure 10 is that in the epitaxial structure 40, the first intermediate layer 301 is provided in the second semiconductor structure 120, that is, the second semiconductor structure 120 includes the first intermediate layer 301. In this embodiment, the first intermediate layer 301 is located between the active region 130 and the second cladding layer 124. As shown in FIG. 4, the first intermediate layer 301 may be adjacent to the active region 130 and the second cladding layer 124. In this embodiment, the first intermediate layer 301 and the second cladding layer 124 have the same conductivity type. In this embodiment, the first intermediate layer 301 does not contain the first dopant. The first intermediate layer 301 and the second cladding layer 124 may include the second dopant. In this embodiment, the second dopant may have maximum concentrations and minimum concentrations in the first intermediate layer 301, the second cladding layer 124, the second window layer 126, and the second contact layer 128. In an embodiment, the maximum concentration of the second dopant in the first intermediate layer 301 is, for example, in a range of greater than or equal to 5×10¹⁷cm⁻³ and less than or equal to1×10¹⁸ cm⁻³, or greater than or equal to 1×10¹⁸ cm⁻³ and less than or equal to 2×10¹⁸cm⁻³. In an embodiment, the maximum concentration of the second dopant in the second cladding layer 124 is, for example, in a range of greater than or equal to 2×10¹⁷cm⁻³ and less than or equal to 1×10¹⁸ cm⁻³. A ratio of the maximum concentration of the second dopant in the first intermediate layer 301 to the maximum concentration of the second dopant in the second cladding layer 124 may be in a range of 0.5 to 10, such as 2 to 5. According to an embodiment, the first intermediate layer 301 is formed, for example, by increasing a doping concentration compared to the doping concentration in a cladding layer that is closest to the first intermediate layer 301 (the second cladding layer 124 in this embodiment) during the epitaxial growth process. The maximum concentration of the second dopant in the first intermediate layer 301 may be greater than the maximum concentration of the second dopant in the second cladding layer 124. The minimum concentration of the second dopant in the first intermediate layer 301 may be greater than the minimum concentration of the second dopant in the second cladding layer 124. The minimum concentration of the second dopant in the first intermediate layer 301 is, for example, within a range of 70% to 99% (such as 75% to 85%) of the maximum concentration of the second dopant in the first intermediate layer 301. The minimum concentration of the second dopant in the second cladding layer 124 is, for example, within a range of 70% to 99% (such as 75% to 85%) of the maximum concentration of the second dopant in the second cladding layer 124. In this embodiment, the thickness of the first intermediate layer 301 may range from greater than or equal to 100 Å to less than or equal to 1000 Å. According to an embodiment, by arranging the first intermediate layer 301 in the second semiconductor structure 120, a capacitance can be further increased, and the anti-ESD capability of the semiconductor device including the epitaxial structure 40 can be improved.

According to an embodiment, relationships between maximum concentrations of the second dopant in each layer of the second semiconductor structure 120 can be: the second contact layer 128>the first intermediate layer 301≥the second window layer 126≥the second cladding layer 124; or, the second contact layer 128>the second window layer 126>the first intermediate layer 301≥the second cladding layer 124. According to an embodiment, relationships between minimum concentrations of the second dopant in each layer of the second semiconductor structure 120 can be: the second contact layer 128>the first intermediate layer 301≥the second window layer 126≥the second cladding layer 124; or, the second contact layer 128>the second window layer 126>the first intermediate layer 301≥the second cladding layer 124. The first intermediate layer 301 may have a first side closer to the active region 130 and a second side farther from the active region 130 relative to the first side. In an embodiment, a concentration of the second dopant on the second side of the first intermediate layer 301 may be greater than the concentration of the second dopant on the first side to further improve reliability and avoid affecting the reliability of the semiconductor device due to the diffusion of the second dopant in the first intermediate layer 301 to the active region 130. The detailed descriptions of positions, relative relationships and materials of each layer or structure as well as structural variations of the epitaxial structure 40 may be referred to the forward embodiments and are not repeatedly described herein.

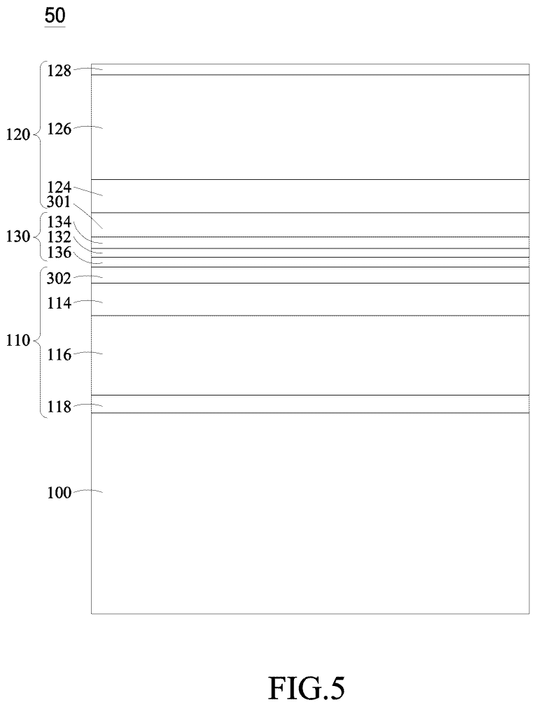

FIG. 5 shows a schematic sectional view of an epitaxial structure 50 in accordance with an embodiment of the present disclosure. The main difference between the epitaxial structure 50 and the epitaxial structure 40 is that in the epitaxial structure 50, the first semiconductor structure 110 further includes the second intermediate layer 302, that is, the second semiconductor structure 120 includes the first intermediate layer 301, and the first semiconductor structure 110 includes the second intermediate layer 302. As shown in FIG. 5, the second intermediate layer 302 is located between the active region 130 and the first semiconductor structure 110. As shown in FIG. 5, the second intermediate layer 302 may be adjacent to the second confinement layer 136 and the first cladding layer 114. In this embodiment, the first intermediate layer 301 and the second intermediate layer 302 have different conductivity types, for example, the first intermediate layer 301 is p-type and the second intermediate layer 302 is n-type. The second intermediate layer 302 may include the first dopant, and the first intermediate layer 301 may include the second dopant. The detailed descriptions of positions, relative relationships and materials of each layer or structure as well as structural variations of the epitaxial structure 50 may be referred to the forward embodiments and are not repeatedly described herein.

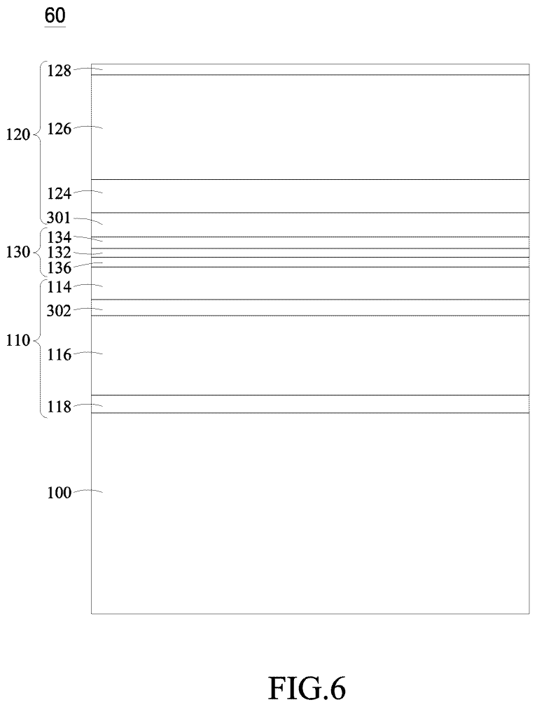

FIG. 6 shows a schematic sectional view of an epitaxial structure 60 in accordance with an embodiment of the present disclosure. The main difference between the epitaxial structure 60 and the epitaxial structure 50 is the position of the second intermediate layer 302. As shown in FIG. 6, in this embodiment, the first cladding layer 114 is located between the active region 130 and the second intermediate layer 302. The detailed descriptions of positions, relative relationships and materials of each layer or structure as well as structural variations of the epitaxial structure 60 may be referred to the forward embodiments and are not repeatedly described herein.

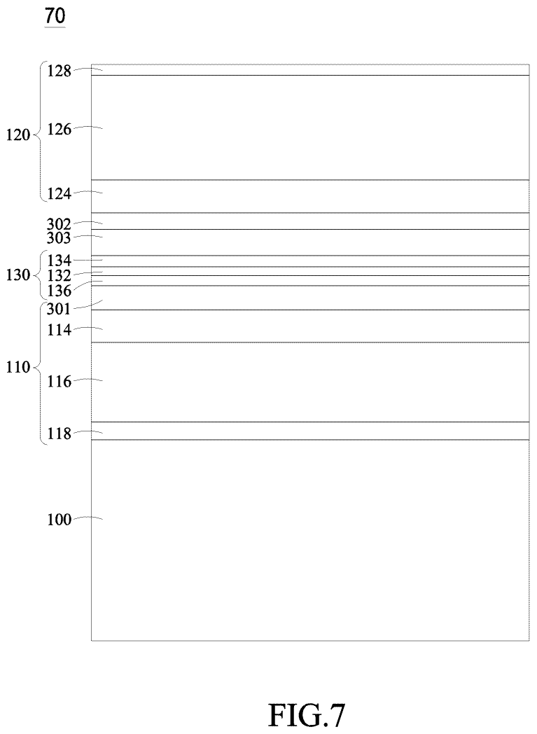

FIG. 7 shows a schematic sectional view of an epitaxial structure 70 in accordance with an embodiment of the present disclosure. The main difference between the epitaxial structure 70 and the epitaxial structure 10 is that the second semiconductor structure 120 also includes the second intermediate layer 302 and the third intermediate layer 303. As shown in FIG. 7, the first intermediate layer 301 is located between the active region 130 and the first cladding layer 114, the second intermediate layer 302 is located between the active region 130 and the second cladding layer 124, and the third intermediate layer 303 is located between the second intermediate layer 302 and the active region 130. The first intermediate layer 301 may include the first dopant, and the second intermediate layer 302 and third intermediate layer 303 may include the second dopant. The second dopant may have maximum concentrations and minimum concentrations in the second intermediate layer 302 and the third intermediate layer 303. In an embodiment, the minimum concentration of the second dopant in the second intermediate layer 302 is lower than the minimum concentration of the second dopant in the second cladding layer 124. The minimum concentration of the second dopant in the second intermediate layer 302 is, for example, in a range of greater than or equal to 1×10¹⁶ cm⁻³ and less than or equal to 1×10¹⁷ cm⁻³. The minimum concentration of the second dopant in the second cladding layer 124 is, for example, in a range of greater than or equal to 2×10¹⁷ cm⁻³ and less than or equal to 1×10¹⁸cm⁻³. The second intermediate layer 302 is formed, for example, by decreasing doping concentration during epitaxial growth. In this embodiment, the second intermediate layer 302 may have a greater resistance than the second cladding layer 124, so that when current passes through, the current can spread laterally first, thereby improving current diffusion. In another embodiment, the third intermediate layer 303 may be located between the active region 130 and the second cladding layer 124, and the second intermediate layer 302 may be located between the third intermediate layer 303 and the active region 130. According to an embodiment, the second intermediate layer 302 is located between the third intermediate layer 303 and the active region 130, which is beneficial to further improving the withstand voltage of the semiconductor device including the epitaxial structure 70.

In this embodiment, the first intermediate layer 301 and the second intermediate layer 302 have different conductivity types. For example, the first intermediate layer 301 is n-type and the second intermediate layer 302 is p-type. The second intermediate layer 302 and the third intermediate layer 303 may have the same conductivity type, such as p type. In an embodiment, a maximum concentration of the second dopant in the third intermediate layer 303 is, for example, in a range of greater than or equal to 5×10¹⁷ cm⁻³ and less than or equal to 1×10¹⁸ cm⁻³, or in a range of greater than or equal to 1×10¹⁸cm⁻³ and less than or equal to 2×10¹⁸ cm⁻³. In an embodiment, the maximum concentration of the second dopant in the second cladding layer 124 is, for example, in a range of greater than or equal to 2×10¹⁷ cm⁻³ and less than or equal to 1×10¹⁸ cm⁻³. A ratio of the maximum concentration of the second dopant in the third intermediate layer 303 to the maximum concentration of the second dopant in the second cladding layer 124 may be in a range of 0.5 to 10, such as 2 to 5. According to an embodiment, the third intermediate layer 303 is formed, for example, by increasing a doping concentration compared to the doping concentration in a cladding layer that is closest to the first intermediate layer 301 (the second cladding layer 124 in this embodiment) during the epitaxial growth process. The maximum concentration of the second dopant in the third intermediate layer 303 may be greater than the maximum concentration of the second dopant in the second cladding layer 124. The minimum concentration of the second dopant in the third intermediate layer 303 may be greater than the minimum concentration of the second dopant in the second cladding layer 124. The minimum concentration of the second dopant in the third intermediate layer 303 is, for example, within the range of 70% to 99% (such as 75% to 85%) of the maximum concentration of the second dopant in the third intermediate layer 303. The thickness of the third intermediate layer 303 may range from greater than or equal to 100 Å to less than or equal to 1000 Å. According to an embodiment, by arranging the third intermediate layer 303 in the second semiconductor structure 120, the capacitance can be further increased, and the anti-ESD capability of the semiconductor device including the epitaxial structure 70 can be improved.

The third intermediate layer 303 may include phosphorus or arsenic. According to an embodiment, the third intermediate layer 303 includes a ternary group III-V semiconductor material (such as InGaAs, AlGaAs, InGaP or AlInP) or a quaternary group III-V semiconductor material (such as AlGaInAs, AlGaInP, InGaAsP or AlGaAsP). The third intermediate layer 303, the second intermediate layer 302 and the second cladding layer 124 may include one or more identical elements, such as Al, In or P. According to an embodiment, relationships between maximum concentrations of the second dopant in each layer of the second semiconductor structure 120 can be: the second contact layer 128>the third intermediate layer 303≥the second intermediate layer 302≥the second window layer 126>the second cladding layer 124; or, the second contact layer 128>the second window layer 126>the third intermediate layer 303≥the second cladding layer 124≥the second intermediate layer 302. According to an embodiment, relationships between minimum concentrations of the second dopant in each layer of the second semiconductor structure 120 can be: the second contact layer 128>the third intermediate layer 303≥the second window layer 126≥the second cladding layer 124>the second intermediate layer 302; or, the second contact layer 128>the second window layer 126>the third intermediate layer 303≥the second cladding layer 124≥the second intermediate layer 302.

In an embodiment, the third intermediate layer 303 may have a first side closer to the active region 130, and a second side farther away from the active region 130 relative to the first side. In an embodiment, a concentration of the second dopant on the second side of the third intermediate layer 303 may be greater than the concentration on the first side to further improve reliability and avoid affecting the semiconductor device due to the diffusion of the second dopant in the third intermediate layer 303 to the active region 130. The detailed descriptions of positions, relative relationships and materials of each layer or structure as well as structural variations of the epitaxial structure 70 may be referred to the forward embodiments and are not repeatedly described herein.

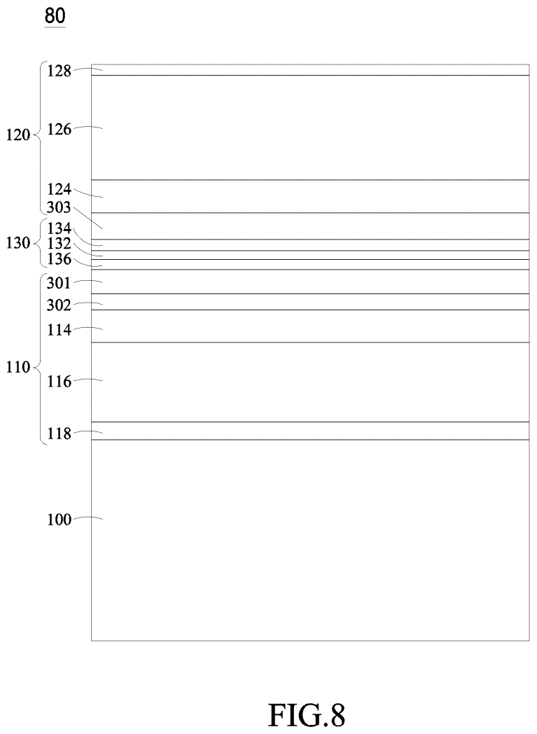

FIG. 8 shows a schematic sectional view of an epitaxial structure 80 in accordance with an embodiment of the present disclosure. The main difference between the epitaxial structure 80 and the epitaxial structure 30 is that the second semiconductor structure 120 further includes a third intermediate layer 303. The third intermediate layer 303 may be located between the active region 130 and the second cladding layer 124. The third intermediate layer 303 and the second cladding layer 124 may include the second dopant. In this embodiment, the first intermediate layer 301 and the second intermediate layer 302 have the same conductivity type, and the first intermediate layer 301 and the third intermediate layer 303 have different conductivity types. For example, the first intermediate layer 301 and the second intermediate layer 302 are n-type, and the third intermediate layer 303 is p-type. The second dopant may have maximum concentrations and minimum concentrations in the second cladding layer 124, the third intermediate layer 303, the second window layer 126 and the second contact layer 128. In an embodiment, the maximum concentration of the second dopant in the third intermediate layer 303 is, for example, in a range of greater than or equal to 5×10¹⁷cm⁻³ and less than or equal to 1×10¹⁸ cm⁻³, or greater than or equal to 1×10¹⁸ cm⁻³ and less than or equal to 2×10¹⁸cm⁻³. In an embodiment, the maximum concentration of the second dopant in the second cladding layer 124 is, for example, in a range of greater than or equal to 2×10¹⁷cm⁻³ and less than or equal to 1×10¹⁸ cm⁻³. A ratio of the maximum concentration of the second dopant in the third intermediate layer 303 to the maximum concentration of the second dopant in the second cladding layer 124 may be in a range of 0.5 to 10, such as 2 to 5. According to an embodiment, the third intermediate layer 303 is formed, for example, by increasing a doping concentration compared to the doping concentration in a cladding layer that is closest to the third intermediate layer 303 (the second cladding layer 124 in this embodiment) during the epitaxial growth process. The maximum concentration of the second dopant in the third intermediate layer 303 may be greater than the maximum concentration of the second dopant in the second cladding layer 124. The minimum concentration of the second dopant in the third intermediate layer 303 may be greater than the minimum concentration of the second dopant in the second cladding layer 124. The minimum concentration of the second dopant in the third intermediate layer 303 is, for example, within a range of 70% to 99% (such as 75% to 85%) of the maximum concentration of the second dopant in the third intermediate layer 303. The minimum concentration of the second dopant in the second cladding layer 124 is, for example, within a range of 70% to 99% (such as 75% to 85%) of the maximum concentration of the second dopant in the second cladding layer 124. According to an embodiment, by arranging the third intermediate layer 303 in the second semiconductor structure 120, the capacitance can be further increased, and the anti-ESD capability of the semiconductor device including the epitaxial structure 80 can be improved.

According to an embodiment, relationships between maximum concentrations of the second dopant in each layer of the second semiconductor structure 120 can be: the second contact layer 128>the third intermediate layer 303≥the second window layer 126≥the second cladding layer 124; or, the second contact layer 128>the second window layer 126>the third intermediate layer 303≥the second cladding layer 124. According to an embodiment, the relationship between the minimum concentration of the second dopant in each layer of the second semiconductor structure 120 can be: the second contact layer 128>the third intermediate layer 303≥the second window layer 126≥the second cladding layer 124; or, the second contact layer 128>the second window layer 126>the third intermediate layer 303≥the second cladding layer 124. The third intermediate layer 303 may have a first side closer to the active region 130 and a second side farther from the active region 130 relative to the first side. In an embodiment, the concentration of the second dopant on the second side of the third intermediate layer 303 may be greater than the concentration of the second dopant on the first side to further improve reliability and avoid affecting the reliability of the semiconductor device due to the diffusion of the second dopant in the third intermediate layer 303 to the active region 130. The detailed descriptions of positions, relative relationships and materials of each layer or structure as well as structural variations of the epitaxial structure 80 may be referred to the forward embodiments and are not repeatedly described herein.

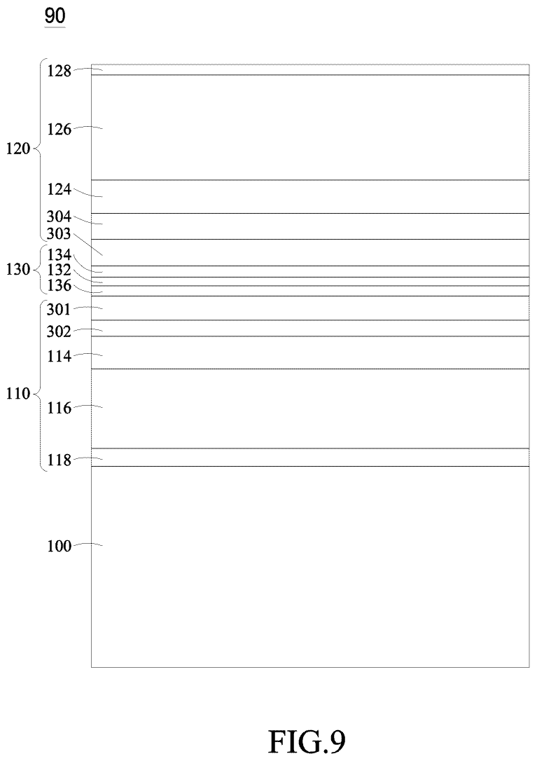

FIG. 9 shows a schematic sectional view of an epitaxial structure 90 in accordance with an embodiment of the present disclosure. Compared with the epitaxial structure 80, the epitaxial structure 90 further includes a fourth intermediate layer 304. That is, in the epitaxial structure 90, the first semiconductor structure 110 includes the first intermediate layer 301 and the second intermediate layer 302, and the second semiconductor structure 120 includes the third intermediate layer 303 and the fourth intermediate layer 304. As shown in FIG. 9, the fourth intermediate layer 304 is located between the third intermediate layer 303 and the second cladding layer 124. In another embodiment, the fourth intermediate layer 304 may be located between the third intermediate layer 303 and the second cladding layer 124. The first intermediate layer 301 and the second intermediate layer 302 may include the first dopant, and the third intermediate layer 303 and the fourth intermediate layer 304 may include the second dopant. In this embodiment, the third intermediate layer 303 and the fourth intermediate layer 304 have the same conductivity type, such as p-type. The second dopant may have maximum concentrations and minimum concentrations in the third intermediate layer 303 and the fourth intermediate layer 304. According to an embodiment, the minimum concentration of the second dopant in the fourth intermediate layer 304 is lower than the minimum concentration of the second dopant in the second cladding layer 124. The minimum concentration of the second dopant in the fourth intermediate layer 304 is, for example, in a range of greater than or equal to 1×10¹⁶ cm⁻³ and less than or equal to 1×10¹⁷ cm⁻³. The minimum concentration of the second dopant in the second cladding layer 124 is, for example, in a range of greater than or equal to 2×10¹⁷ cm⁻³ and less than or equal to 1×10¹⁸ cm⁻³. The fourth intermediate layer 304 is formed, for example, by decreasing doping concentration during epitaxial growth. In this embodiment, the fourth intermediate layer 304 may have a greater resistance than the second cladding layer 124, so that when current passes through, the current can spread laterally first, thereby improving current diffusion. A thickness of the fourth intermediate layer 304 may range from greater than or equal to 200 Å to less than or equal to 1000 Å.

The fourth intermediate layer 304 may include phosphorus or arsenic. According to an embodiment, the fourth intermediate layer 304 includes a ternary group III-V semiconductor material (such as InGaAs, AlGaAs, InGaP, or AlInP) or a quaternary group III-V semiconductor material (such as AlGaInAs, AlGaInP, InGaAsP, or AlGaAsP). According to an embodiment, by further arranging the fourth intermediate layer 304 in the epitaxial structure, the current spreading ability can be increased, and it can also help to improve the anti-ESD capability of the semiconductor device including the epitaxial structure 90. In an embodiment, the third intermediate layer 303, the fourth intermediate layer 304 and the second cladding layer 124 may have one or more identical elements, such as Al, In or P. In an embodiment, the third intermediate layer 303 and the fourth intermediate layer 304 (or the second cladding layer 124) have different composition elements. For example, the third intermediate layer 303 includes a quaternary group III-V semiconductor material, and the fourth intermediate layer 304 includes a ternary group III-V semiconductor material. According to an embodiment, relationships between the maximum concentrations of the second dopant in each layer of the second semiconductor structure 120 can be: the second contact layer 128>the third intermediate layer 303≥the fourth intermediate layer 304≥the second window layer 126>the second cladding layer 124; or, the second contact layer 128>the second window layer 126>the third intermediate layer 303≥the second cladding layer 124≥the fourth intermediate layer 304. According to an embodiment, relationships between the minimum concentrations of the second dopant in each layer of the second semiconductor structure 120 can be: the second contact layer 128>the third intermediate layer 303≥the second window layer 126≥the second cladding layer 124>the fourth intermediate layer 304; or, the second contact layer 128>the second window layer 126>the third intermediate layer 303≥the second cladding layer 124≥the fourth intermediate layer 304. The detailed descriptions of positions, relative relationships and materials of each layer or structure as well as structural variations of the epitaxial structure 90 may be referred to the forward embodiments and are not repeatedly described herein.

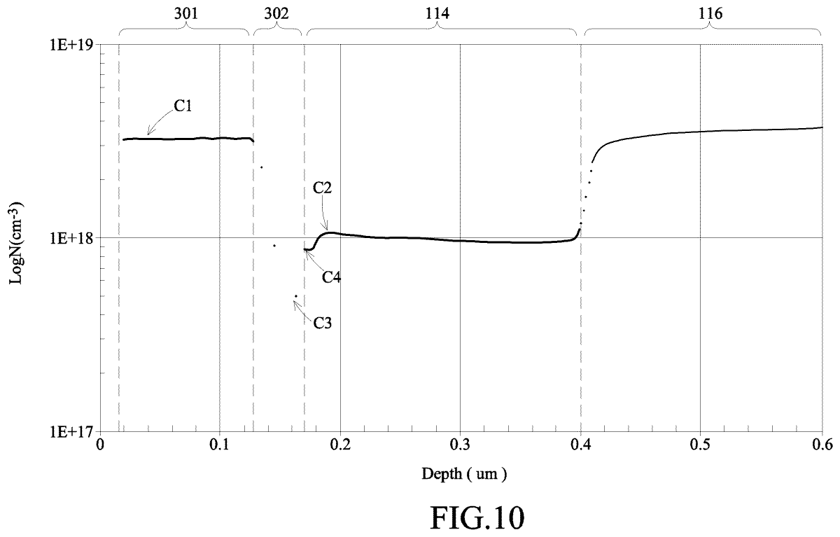

FIG. 10 shows a diagram of dopant concentration in a partial region of the epitaxial structure 30 of FIG. 3. Specifically, FIG. 10 shows the results of analyzing a portion of the epitaxial structure 30 (which includes the first intermediate layer 301, the second intermediate layer 302, the first cladding layer 114 and the first window layer 116) by ECV. In this embodiment, the first intermediate layer 301, the second intermediate layer 302 and the first cladding layer 114 include a ternary group III-V semiconductor material (such as AlInP), and the first window layer 116 includes a quaternary group III-V semiconductor material (such as AlGaInP). The first intermediate layer 301, the second intermediate layer 302, the first cladding layer 114 and the first window layer 116 all include the first dopant (such as Si). As shown in FIG. 10, the maximum concentration (C1) of the first dopant in the first intermediate layer 301 is greater than the maximum concentration (C2) of the first dopant in the first cladding layer 114. The second intermediate layer 302 is adjacent to the first intermediate layer 301 and the first cladding layer 114, and the concentration of the first dopant in the second intermediate layer 302 decreases from a side close to the first intermediate layer 301 to another side close to the first cladding layer 114. The minimum concentration (C3) of the first dopant in the second intermediate layer 302 is lower than the minimum concentration (C4) of the first dopant in the first cladding layer 114. The maximum concentration (C5) of the first dopant in the first window layer 116 may be greater than or equal to the maximum concentration (C1) of the first dopant in the first intermediate layer 301. In this embodiment, by arranging the first intermediate layer 301 and the second intermediate layer 302, it is beneficial to improve the current diffusion of the epitaxial structure, thereby improving the anti-ESD capability of the semiconductor device including the epitaxial structure.

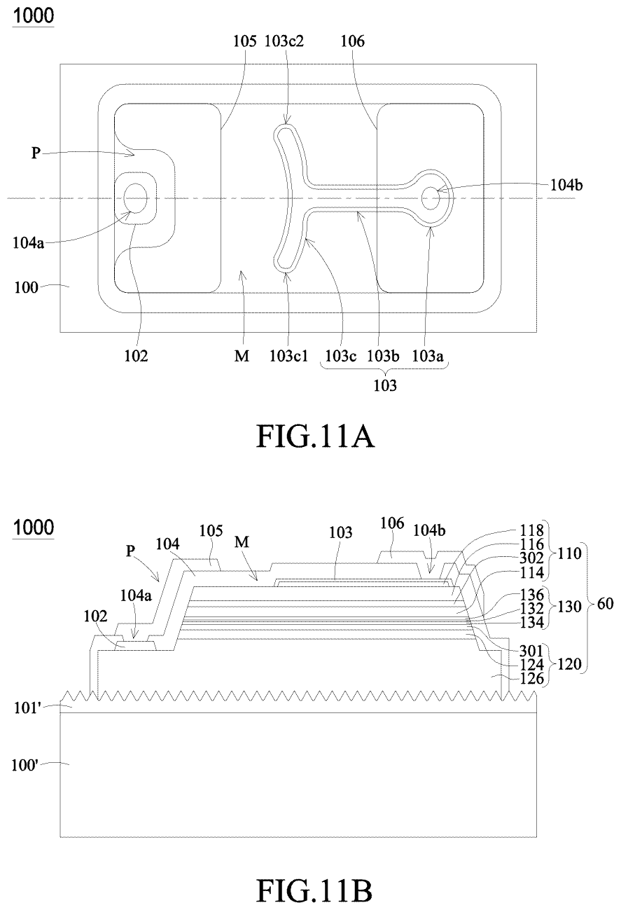

FIG. 11A shows a schematic top view of a semiconductor device 1000 in accordance with an embodiment of the present disclosure. FIG. 11B shows a schematic sectional view of the semiconductor device 1000 in accordance with an embodiment of the present disclosure. Specifically, the semiconductor device 1000 may include an epitaxial structure (such as the epitaxial structure 10, 20, 30, 40, 50, 60, 70, 80 or 90) as described in an embodiment of the present disclosure. For ease of understanding, the epitaxial structure 60 is taken as an example for description here. In this embodiment, the second semiconductor structure 120 in the epitaxial structure 60 sequentially includes the first intermediate layer 301, the second cladding layer 124 and the second window layer 126 in a direction from close to the active region 130 to away from the active region 130. In this embodiment, the second window layer 126 may serve as a current diffusion layer and a contact layer, so the second semiconductor structure 120 does not have the second contact layer 128. In another embodiment, the second semiconductor structure 120 may have the second contact layer 128. The first semiconductor structure 110 sequentially includes the first cladding layer 114, the second intermediate layer 302, the first window layer 116 and the first contact layer 118 in a direction from close to the active region 130 to away from the active region 130. In an embodiment, an area of the semiconductor device 1000 is, for example, in a range of 5000 μm² to 15000 μm².

As shown in FIGS. 11A and 11B, the epitaxial structure 60 has a recess portion P, and the second window layer 126 is exposed from the recess portion P. The first semiconductor structure 110, the active region 130 and a part of the second semiconductor structure 120 form a mesa structure M. The semiconductor device 1000 includes a first metal contact structure 102, a second metal contact structure 103, an insulating structure 104, a first electrode 105 and a second electrode 106. The first metal contact structure 102 is located on the second window layer 126 and is in direct contact with the second window layer 126 to form an electrical connection. The second metal contact structure 103 is located on the first contact layer 118 and is in direct contact with the first contact layer 118 to form an electrical connection. The insulating structure 104 covers the epitaxial structure 60 and has a first opening 104a corresponding to the first metal contact structure 102 and a second opening 104b corresponding to the second metal contact structure 103. The first electrode 105 fills the first opening 104a and is in direct contact with the first metal contact structure 102. The second electrode 106 fills the second opening 104b and is in direct contact with the second metal contact structure 103.

As shown in FIG. 11A, when viewed from above, the mesa structure M has a shape with multiple rounded corners. The first metal contact structure 102 is arranged in the recess portion P. The second metal contact structure 103 may optionally include a first portion 103a , a second portion 103b , and a third portion 103c . The first portion 103a is located directly under the second opening 104b to be in direct contact with the second electrode 106. The second portion 103b and the third portion 103c extend from the first portion 103a toward the first metal contact structure 102 (or the first electrode 105). As shown in FIG. 11A and FIG. 11B, the second portion 103b and the third portion 103c do not overlap with the second electrode 106 in a vertical direction. When viewed from above, the third portion 103c may be arc-shaped and may have a first end part 103c1 and a second end part 103c2 extending in different directions, thereby further dispersing current and improving current diffusion of the device during operation of the semiconductor device. In an embodiment, the second metal contact structure 103 may include the first portion 103a and the second portion 103b without including the third portion 103c , and the second portion 103b may be overlapped with the second electrode 106 in a vertical direction. In an embodiment, the first metal contact structure 102 may have one or more finger-like ends (not shown) extending toward the second electrode 106 to improve current spreading of the element.

In an embodiment, the first metal contact structure 102 and the second metal contact structure 103 may include metal or alloy. The metal may include germanium (Ge), beryllium (Be), zinc (Zn), gold (Au), nickel (Ni) or copper (Cu). The alloy may include two or more metals selected from above metals, such as germanium gold nickel (GeAuNi), beryllium gold (BeAu), germanium gold (GeAu), or zinc gold (ZnAu). The insulating structure 104 includes a dielectric material. The dielectric material is, for example, an oxide or a nitride, such as tantalum oxide (TaOx), aluminum oxide (AlOx), silicon dioxide (SiOx), titanium oxide (TiOx) or silicon nitride (SiNx). In an embodiment, the insulating structure 104 includes a reflective structure, such as a Distributed Bragg Reflector (DBR) structure. The first electrode 105 and the second electrode 106 may each include a single layer or a multi-layer structure. In an embodiment, the first electrode 105 and the second electrode 106 include one or more metals selected from nickel (Ni), titanium (Ti), platinum (Pt), palladium (Pd), silver (Ag), gold (Au), aluminum (Al), tin (Sn), and copper (Cu).

The semiconductor device 1000 may optionally include a base 100′ and an adhesive layer 101′. As shown in FIG. 11A and FIG. 11B, the epitaxial structure 60 can be connected to the base 100′ through the adhesive layer 101′. For the base 100′, the description of the base 100 can be referred to. The material of the adhesive layer 101 'may include an insulating material and/or a conductive material. The insulating material includes but is not limited to polyimide (PI), benzocyclobutene (BCB), perfluorocyclobutane (PFCB), magnesium oxide (MgO), Su8, epoxy resin, acrylic resin, cyclic olefin polymer (COC), polymethyl methacrylate (PMMA), polyethylene terephthalate (PET), polycarbonate (PC), polyetherimide, fluorocarbon polymer, glass, aluminum oxide (Al₂O₃), silicon oxide (SiO₂), titanium oxide (TiO₂), silicon nitride (SiₓN_{y}) or spin-on glass (SOG). The conductive material includes but is not limited to indium tin oxide (ITO), indium oxide (InO), tin oxide (SnO), cadmium tin oxide (CTO), antimony tin oxide (ATO), aluminum zinc oxide (AZO), zinc tin oxide (ZTO), zinc oxide (ZnO), indium zinc oxide (IZO), tantalum oxide (Ta₂O₅), diamond-like carbon film (DLC) or gallium zinc oxide (GZO). The detailed descriptions of positions, relative relationships and materials of the layers or structures as well as structural variations in this embodiment may be referred to the forward embodiments and are not repeatedly described herein.

According to an embodiment, an anti-ESD capability test can be performed on a semiconductor device without an intermediate layer and a semiconductor device 1000 with an intermediate layer (such as the epitaxial structure 10, 20, 30, 40, 50, 60, 70, 80 or 90). The above test can be performed using a test method such as human body model (HBM) testing (for example, the test can be performed based on the U.S. military standard method MIL-STD-883, the Solid State Technology Association standard method ESDA-JEDEC JS-001, or the Automotive Electronics Council standard method AEC-Q100-002). The results show that under the same test voltage, compared with a semiconductor device without an intermediate layer, yield rates of the semiconductor device 1000 with the first intermediate layer 301, the second intermediate layer 302, the third intermediate layer 303 and/or the fourth intermediate layer 304 can be significantly improved, and higher withstand voltages can be obtained. For example, when the areas of the devices are the same (such as 4 mil×6 mil (1 mil=25.4 um)), under a test voltage of 1450V, a yield rate of a semiconductor device 1000 with the first intermediate layer 301 can be increased by more than 40% compared to that of a semiconductor device without an intermediate layer; under a test voltage of 1750V, a yield rate of a semiconductor device 1000 with the first intermediate layer 301 and the second intermediate layer 302 can be further improved by more than 30% compared to that of the semiconductor device 1000 with the first intermediate layer 301. In addition, withstand voltages of the semiconductor devices 1000 with the first intermediate layer 301, the second intermediate layer 302, the third intermediate layer 303 and/or the fourth intermediate layer 304 can reach a range of 1800V to 2700V, which are significantly greater than that of a semiconductor device without an intermediate layer. Based on above, it can be understood that by introducing the intermediate layer(s), the anti-ESD capability of semiconductor device(s) can be improved and the yield rate(s) can be further improved.

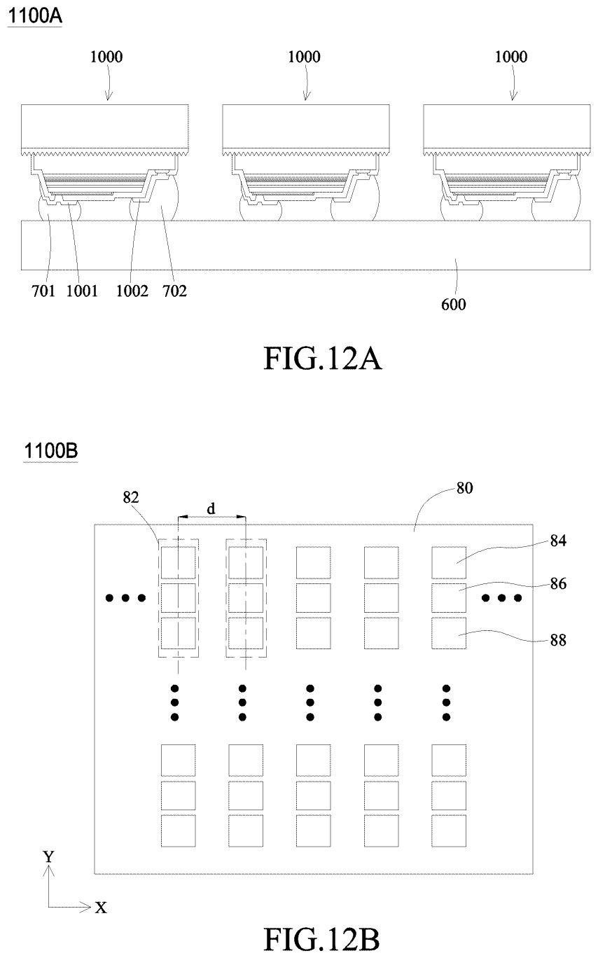

FIG. 12A shows a schematic sectional view of a semiconductor component 1100A in accordance with an embodiment of the present disclosure. Specifically, FIG. 12A illustrates a semiconductor component 1100A formed by flip-chip bonding a plurality of semiconductor devices 1000 to a carrier 600. Each semiconductor device 1000 may include an epitaxial structure (such as the epitaxial structure 10, 20, 30, 40, 50, 60, 70, 80 or 90) as described in an embodiment of the present disclosure. The semiconductor component 1100A includes a carrier 600 and a plurality of semiconductor devices 1000 located on the carrier 600. Each semiconductor device 1000 includes a first electrode pad 1001 and a second electrode pad 1002. The semiconductor component 1100A also includes a plurality of first conductive bumps 701 and a plurality of second conductive bumps 702. The first conductive bumps 701 connects the first electrode pads 1001 to the carrier 600, and the second conductive bumps 702 connects the second electrode pads 1002 to the carrier 600. The carrier 600 is, for example, a package submount or a printed circuit board (PCB). The carrier 600 may have a single-layer or multi-layer structure. The material of the carrier 600 may include polyester (PE), polyimide (PI), BT (Bismaleimide Triazine) resin, PTFE (Polytetrafluoroethylene) resin, phenol (PF) resin or fiberglass epoxy resin (FR4). The material of the first conductive bumps 701 and the second conductive bumps 702 may include metal, such as tin (Sn). The detailed descriptions of positions, relative relationships and materials of the layers or structures as well as structural variations in this embodiment may be referred to the forward embodiments and are not repeatedly described herein.

FIG. 12B shows a schematic top view of a semiconductor component 1100B in accordance with an embodiment of the present disclosure. The semiconductor component 1100B of the embodiment is, for example, a display. As shown in FIG. 12B, the semiconductor component 1100B includes a carrier 800 and a plurality of pixel units 82 on the carrier 800. The pixel units 82 are arranged in an array along the directions parallel to the X-axis and the Y-axis, and are arranged at an interval d in the direction parallel to the X-axis. The number of pixel units 82 can be adjusted based on actual needs. For example, in an embodiment, a display with a resolution of 1920x1080 pixels can be provided by the plurality of pixel units 82 included in the semiconductor component 1100B. In an embodiment, the interval d is less than 1.4 mm, for example, and the interval d can be in a range of 0.2 mm to 1.3 mm, such as 0.75 mm, 0.8 mm, 1 mm or 1.25 mm. As shown in FIG. 12B, each pixel unit 82 includes a first semiconductor device 84, a second semiconductor device 86, and a third semiconductor device 88 arranged in a direction parallel to the Y-axis. One or more of the first semiconductor device 84, the second semiconductor device 86, and the third semiconductor device 88 may be a semiconductor device (such as the semiconductor device 1000) having an epitaxial structure (such as the epitaxial structure 10, 20, 30, 40, 50, 60, 70, 80 or 90) described in the embodiments of the present disclosure. In an embodiment, the first semiconductor device 84, the second semiconductor device 86, and the third semiconductor device 88 are all light-emitting devices and can emit red light, green light, and blue light, respectively. In an embodiment, the arrangement order of the light-emitting devices can also be adjusted based on actual needs. For example, the first semiconductor device 84, the second semiconductor device 86, and the third semiconductor device 88 emit red light, blue light, and green light, respectively. Each pixel unit 82 can be electrically connected to a circuit (not shown) on the surface of the carrier 800, so that the light-emitting devices therein can receive an external signal and emit light in accordance with the external signal. Regarding the structure or material of the carrier 800, above description for the carrier 600 can be referred to. In an embodiment, the carrier 800 can be bent, and for example, can withstand a radius of curvature less than 50 mm, such as 25 mm or 32 mm.

Based on above, according to the embodiment(s) of the present disclosure, an epitaxial structure, a semiconductor device and a semiconductor component may be provided. For example, by arranging one or more intermediate layers, the current diffusion and the anti-electrostatic discharge (anti-ESD) capability of the semiconductor device can be improved. Specifically, the epitaxial structure, the semiconductor device and the semiconductor component of the present disclosure may be applied to products in various fields, such as illumination, display, communication or power supply system, for example, may be used in a light fixture, monitor, an automotive instrument panel, a television, computer, traffic sign, or an outdoor display device.

It should be realized that each of the embodiments mentioned in the present disclosure is used for describing the present disclosure, but not for limiting the scope of the present disclosure. Any obvious modification or alteration is not departing from the spirit and scope of the present disclosure. Furthermore, embodiments may be combined or substituted under proper condition and are not limited to specific embodiments described above. A connection relationship between a specific component and another component specifically described in an embodiment may also be applied in another embodiment and is within the scope as claimed in the present disclosure.

What is claimed is:

1. A semiconductor device, comprising:
an epitaxial structure, comprising:
a first semiconductor structure having a first conductivity type and comprising a first intermediate layer and a first cladding layer;
a second semiconductor structure having a second conductivity type; and
an active region located between the first semiconductor structure and the second semiconductor structure;
wherein the first intermediate layer is located between the active region and the first cladding layer and comprises P or As, the first intermediate layer and the first cladding layer comprise a first dopant, wherein a maximum concentration of the first dopant in the first intermediate layer is greater than a maximum concentration of the first dopant in the first cladding layer.

2. The semiconductor device of claim 1, wherein the first semiconductor structure further comprises a second intermediate layer located between the first intermediate layer and the first cladding layer.

3. The semiconductor device of claim 2, wherein the second intermediate layer comprises the first dopant, and a minimum concentration of the first dopant in the second intermediate layer is less than a minimum concentration of the first dopant in the first cladding layer.

4. The semiconductor device of claim 3, wherein the second semiconductor structure comprises a third intermediate layer and a second cladding layer, wherein the third intermediate layer is located between the active region and the second cladding layer.

5. The semiconductor device of claim 4, wherein the third intermediate layer and the second cladding layer comprise a second dopant different from the first dopant.

6. The semiconductor device of claim 5, wherein a maximum concentration of the second dopant in the third intermediate layer is greater than a maximum concentration of the second dopant in the second cladding layer.

7. The semiconductor device of claim 6, wherein the second semiconductor structure further comprises a fourth intermediate layer located between the third intermediate layer and the second cladding layer.

8. The semiconductor device of claim 7, wherein the fourth intermediate layer comprises the second dopant, and a minimum concentration of the second dopant in the fourth intermediate layer is less than a minimum concentration of the second dopant in the second cladding layer.

9. The semiconductor device of claim 1, wherein the first intermediate layer comprises a ternary or quaternary group III-V semiconductor material.

10. The semiconductor device of claim 1, wherein the maximum concentration of the first dopant in the first intermediate layer is in a range of 2×10¹⁸ cm⁻³ to 8×10¹⁸ cm⁻³.

11. The semiconductor device of claim 1, wherein a minimum concentration of the first dopant in the first intermediate layer is greater than a minimum concentration of the first dopant in the first cladding layer.

12. The semiconductor device of claim 1, wherein a ratio of the maximum concentration of the first dopant in the first intermediate layer to the maximum concentration of the first dopant in the first cladding layer is in a range of 1 to 5.

13. The semiconductor device of claim 1, wherein the first semiconductor structure further comprising a second intermediate layer, and the first cladding layer is located between the first intermediate layer and the second intermediate layer.

14. The semiconductor device of claim 13, wherein the second intermediate layer comprise the first dopant, and a minimum concentration of the first dopant in the second intermediate layer is less than a minimum concentration of the first dopant in the first cladding layer.

15. The semiconductor device of claim 1, wherein the second semiconductor structure comprises a second intermediate layer and a second cladding layer.

16. The semiconductor device of claim 15, wherein the second intermediate layer is located between the active region and the second cladding layer.

17. The semiconductor device of claim 15, wherein the second cladding layer is located between the active region and the second intermediate layer.

18. The semiconductor device of claim 15, wherein the second intermediate layer and the second cladding layer comprise a second dopant different from the first dopant.

19. The semiconductor device of claim 18, wherein a minimum concentration of the second dopant in the second intermediate layer is less than a minimum concentration of the second dopant in the second cladding layer.

20. A semiconductor component, comprising:
a carrier;
a semiconductor device located on the carrier and comprising:
an epitaxial structure, comprising:
a first semiconductor structure having a first conductivity type and comprising a first intermediate layer and a first cladding layer;
a second semiconductor structure having a second conductivity type; and
an active region located between the first semiconductor structure and the second semiconductor structure; and
a first conductive bump and a second conductive bump located between the semiconductor device and the carrier;
wherein the first intermediate layer is located between the active region and the first cladding layer and comprises P or As, the first intermediate layer and the first cladding layer comprise a first dopant, wherein a maximum concentration of the first dopant in the first intermediate layer is greater than a maximum concentration of the first dopant in the first cladding layer.
